(19) United States
(12) Patent Application Publication
(10) Pub. No.: US 2025/0204259 A1
(43) Pub. Date: Jun. 19, 2025

(54) THINNING METHOD

(71) Applicant: Commissariat à I'Énergie Atomique et aux Énergies Altenatives, Paris (FR)

(72) Inventors: Marie Bousquet, Grenoble (FR); Pierre Perreau, Grenoble (FR); Grégory Enyedi, Grenoble (FR); Marianne Coig, Grenoble (FR)

(73) Assignee: Commissariat à I'Énergie Atomique et aux Énergies Altenatives, Paris (FR)

(21) Appl. No.: 18/980,346

(22) Filed: Dec. 13, 2024

(30) Foreign Application Priority Data
Dec. 18, 2023 (FR) 2314364

(51) Int. Cl. H10N 30/086; H03H 9/56

(52) U.S. Cl. CPC H10N 30/086; H03H 9/564

(57) ABSTRACT

A method for thinning a first layer made of a piezoelectric material including: the implantation of ions into the first layer so as to amorphize an upper portion of the first layer, and the removal of the upper portion by a chemical-mechanical polishing step.

### CROSS REFERENCE TO RELATED APPLICATION

This application claims the priority benefit of French patent application number FR2314364, filed on Dec. 18, 2023, entitled “Procédé d′amincissement”, the content of which is hereby incorporated by reference to the maximum extent allowable by law.

### TECHNICAL FIELD

The present disclosure generally concerns electronic devices and their manufacturing methods. More particularly, the present disclosure concerns electronic devices comprising piezoelectric layers and their manufacturing methods.

### PRIOR ART

There exist known methods for manufacturing a device comprising a thin layer of a piezoelectric material on a substrate. For example, document WO 2019/002080 teaches a method known as Smart Cut™ for transferring a thin layer from a support onto a substrate.

The Smart Cut™ method, as well as other methods for manufacturing a device comprising a layer of a piezoelectric material on a substrate, comprise a step of thinning by grinding of the layer of piezoelectric material. This grinding step results in surface defects on the layer of piezoelectric material.

### SUMMARY OF THE INVENTION

An embodiment provides a method for thinning a first layer made of a piezoelectric material comprising: a. the implantation of ions into the first layer so as to amorphize an upper portion of the first layer, and b. the removal of the upper portion by a chemical-mechanical polishing step.

According to an embodiment, the first layer is made of a material from among LiNbO₃, LiTaO₃, quartz, langasite, langatate, KNbO₃, K(Ta, Nb)O₃, SrTiO₃, or Pb(Zr, Ti)O₃.

According to an embodiment, the ions comprise hydrogen and/or helium and/or oxygen ions.

According to an embodiment, the first layer is located on a substrate.

According to an embodiment, the first layer is obtained by a grinding step.

According to an embodiment, the method comprises an anneal step between steps a. and b.

According to an embodiment, the characteristics of step a. are such that the rate of removal of the upper portion of the first layer by polishing is at least 10% faster than the rate of removal of a lower portion having received no ions from the first layer by polishing.

According to an embodiment, the lower portion has a thickness smaller than 10 μm.

According to an embodiment, the lower portion has a thickness smaller than 1 μm.

According to an embodiment, the method comprises a plurality of distinct ion implantation steps.

Another embodiment provides a method for manufacturing a surface acoustic wave filter comprising: the forming of a first layer made of a piezoelectric material on a substrate; the thinning of the first layer by a method such as previously described; the forming of electrodes having shapes of interdigitated combs on the first layer.

Another embodiment provides a method for manufacturing a bulk acoustic wave filter comprising: the forming of a second layer on a substrate; the forming of a first conductive or semiconductor region in the second layer; the forming of a first layer on the second layer; the thinning of the first layer by a method such as previously described; the forming of a cavity through the first layer so as to reach the first conductive or semiconductor region; the forming of a second conductive region on the first layer.

According to an embodiment, the second layer is a Bragg mirror.

According to an embodiment, the method comprises the forming of a cavity comprising a gaseous element between a portion of the first region and the second layer.

According to an embodiment, the filter is adapted to radio frequencies.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A shows a step of a thinning method;

FIG. 1B shows another step of the method of FIG. 1A;

FIG. 1C shows another step of the method of FIG. 1A;

FIG. 2 shows a step of another thinning method;

FIG. 3 shows a filter comprising a piezoelectric layer;

FIG. 4 shows a filter comprising a piezoelectric layer; and

FIG. 5 shows a filter comprising a piezoelectric layer.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

A piezoelectric material is defined as a material having the property of electrically polarizing under the action of mechanical stress and, conversely, of deforming when an electric field is applied thereto. A category of piezoelectric materials corresponds to ferroelectrics, that is, materials having an electrical polarization in the natural state that can be reversed by the application of an external electric field. Another category of piezoelectric materials corresponds to pyroelectric materials, that is, materials in which a variation in electrical polarization can be generated by a temperature change of the material.

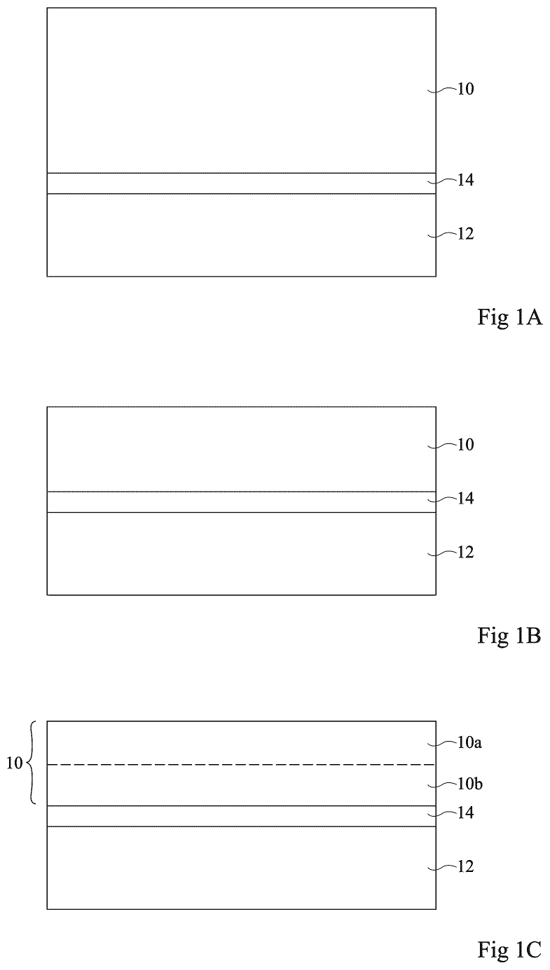

FIGS. 1A, 1B, and 1C show steps, preferably successive, of a method for thinning a layer made of a piezoelectric material. The method of FIGS. 1A, 1B, and 1C for example enables to obtain a so called thin-film layer made of a piezoelectric material. The desired thin film is preferably planar, that is, having parallel and planar upper and lower surfaces, opposite to each other.

FIG. 1A shows a step of a thinning method.

During this step, a layer 10 of a piezoelectric material is bonded to a support 12.

Support 12 is for example a semiconductor substrate, for example made of silicon (Si), of silicon carbide (SiC), or of diamond. For example, support 12 corresponds to the manipulator substrate, also called handle substrate, or base, of the thinning method.

As a variant, support 12 may comprise a plurality of materials, for example a plurality of layers of different materials. Support 12 corresponds, for example, to the substrate of a chip on which a filter can be formed.

Layer 10 is made of a piezoelectric material, preferably of a single-crystal piezoelectric material. Layer 10 is for example made of a ferroelectric material or of a pyroelectric material. For example, layer 10 is made of LiNbO₃, of LiTaO₃, of quartz, of langasite, of langatate, of KNbO₃, of K(Ta, Nb)O₃, of SrTiO₃, or of Pb(Zr, Ti)O₃.

Layer 10 corresponds, for example, to a solid block of piezoelectric material. Layer 10 is for example obtained from an ingot made of a piezoelectric material having been cut and thinned to obtain said solid block.

Layer 10 is bonded to substrate 12. The layer is for example bonded by molecular bonding. Layer 10 is for example bonded to support 12 by a tie layer 14, or bonding layer 14. Layer 14 is for example made of a dielectric material, for example of silicon oxide (SiO₂), of silicon nitride (SiN), of Al₂O₃ or of HfO₂, of a polymer or of a metal, for example gold, tungsten, platinum, or titanium.

In other words, support 12 comprises an upper surface, that is, the surface closest to layer 10, covered by bonding layer 14, more precisely by a lower surface of bonding layer 14. Bonding layer 14 is covered by layer 10. More precisely, the upper surface of bonding layer 14 is covered by a lower surface of layer 10.

The thickness of support 12 is for example in the range from 50 μm to 2,000 mm, for example substantially equal to 100 μm, 150 μm, or 200 μm.

The thickness of layer 10 is greater than the desired thickness after the application of the thinning method. Layer 10 for example has a thickness in the range from 5 to 2,000 μm.

FIG. 1B shows another step of the method of FIG. 1A.

The step of FIG. 1B corresponds to a first thinning step. This thinning step for example removes a significant part of the thickness of layer 10, for example at least half of layer 10. It preferably is a grinding step.

The step of FIG. 1B, that is, the grinding step, results in the forming of defects on the upper surface of layer 10, that is, on the ground surface. Said surface defects correspond, for example, to a lack of uniformity of the thickness of layer 10, for example cracks in layer 10. Thus, certain regions of layer 10 after grinding comprise unwanted cavities in the upper surface. Further, the grinding step may have generated degradations of electrical characteristics of layer 10 at the upper surface.

The thickness of layer 10 after the grinding step is greater than the desired thickness after the application of the thinning method. More precisely, the grinding step is such that the thickness of layer 10 after the grinding is greater than the sum of the thickness desired after application of the thinning method and of the maximum thickness of the defects generated by the grinding. For example, the thickness of layer 10 after the step of FIG. 1B is in the range from 15 μm to 50 μm.

FIG. 1C shows another step of the method of FIG. 1A.

During this step, an upper portion 10a is formed in layer 10. Portion 10a extends from the upper surface of layer 10. Portion 10a extends towards the lower surface of layer 10. Portion 10a corresponds to the entire upper portion of layer 10.

Layer 10 further has a lower portion 10b. Portion 10b corresponds to the entire portion of layer 10 extending between portion 10a and support 12. Thus, layer 10 corresponds to a stack of portion 10b and of portion 10a.

Portion 10b has a thickness greater than or equal to, preferably substantially equal to, the height of layer 10 desired after the thinning method. Portion 10a has a thickness greater than or equal to, preferably greater than, the maximum height of the surface defects generated by grinding.

Portion 10a is obtained by the introduction into layer 10of at least one so-called light species. The introduction of said light species corresponds, for example, to an implantation, that is, to an ion bombardment of the upper surface of layer 10 by light ions, for example hydrogen and/or helium and/or oxygen ions, and optionally by heavier ions, for example argon or carbon. For example, portion 10a is obtained by a cointegration, that is, the integration of a plurality of ions. Portion 10a thus corresponds to a so-called amorphized, or damaged, portion of layer 10.

The nature, the dose of the implanted species, and the implantation energy are selected according to the thickness of the defects and to the thickness of the desired thinning. It is thus possible to form a layer, corresponding to portion 10b, having, depending on applications, a thickness greater than 10 μm, a thickness in the range from 1 μm to 10 μm, or a thickness smaller than 1 μm.

The ion implantation method, highly homogeneous at the scale of a plate, ensures that portion 10a has a planar lower surface, preferably parallel to the lower surface of layer 10, more preferably parallel to the upper surface of layer 10.

The step of FIG. 1C comprises, for example, a step of annealing of the structure.

The thinning method comprises, after the step of FIG. 1C, a step of chemical-mechanical polishing (CMP). The polishing step enables to remove portion 10a. The layer formed by the thinning method thus corresponds to portion 10b.

The degradation of portion 10a of the layer 10 of piezoelectric material causes a change in the etching rate, or rate of removal, of the piezoelectric material of portion 10b. Thus, the material of portion 10a is etched faster, for example at least 10% faster, than the material of portion 10a. For example, in the case of a layer 10 made of LiNbO₃, portion 10a is etched 30% faster than portion 10b.

It is thus possible to remove portion 10a without etching or damaging portion 10b. The difference in etching speed ensures that the height differences of portion 10a caused by surface defects do not impact the upper surface of portion 10b. Portion 10b thus has a planar upper surface, with no surface defects caused by the grinding.

As a variant, the method of FIGS. 1A to 1C may be used to decrease a non-uniformity after a polishing and before a trimming step.

As a variant, layers 10 and 14 may be replaced by a layer of piezoelectric material obtained by physical vapor deposition or chemical vapor deposition.

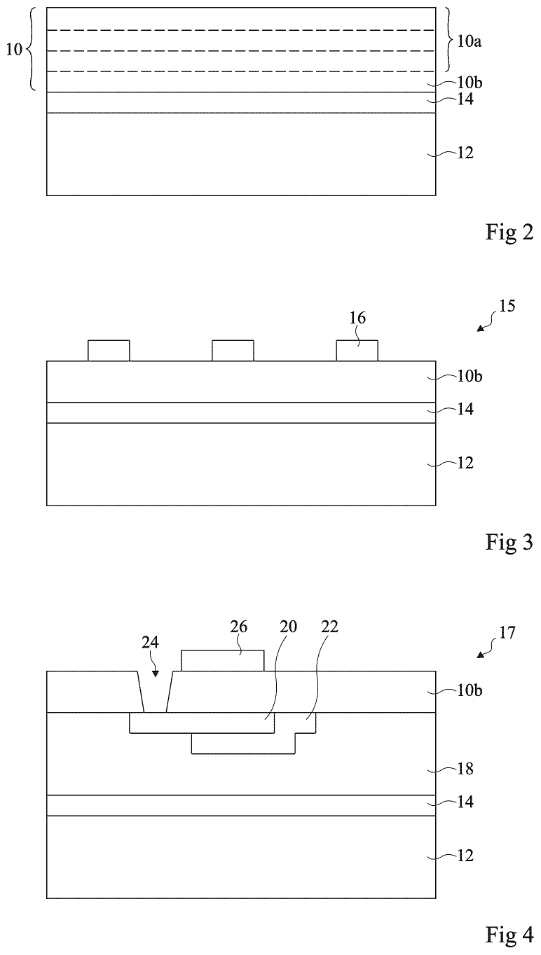

FIG. 2 shows a step of another thinning method. More specifically, FIG. 2 illustrates a variant of the manufacturing method of FIGS. 1A to 1C. The variant of FIG. 2 is, for example, particularly adapted to the forming of a thin layer, for example smaller than 10 μm. FIG. 2 more specifically illustrates a variant of the step of FIG. 1C.

The method illustrated in FIG. 2 comprises, like the method of FIGS. 1A to 1C, the steps of FIGS. 1A and 1B.

The step of FIG. 2 differs from the step of FIG. 1C in that layer 10 undergoes, prior to the polishing step, a plurality of ion implantations, each implantation being represented by a dotted line in FIG. 2. More specifically, the dotted lines indicate the lower level of the ion-receiving portion for each implantation. Each implantation is followed, for example, by an anneal. Each implantation is performed at a different depth. The implantations may be performed at depths for example smaller than 500 nm, for example smaller than 300 nm, for example smaller than 200 nm.

At least some of the different implantations are for example performed with different ions and/or different energy levels.

FIG. 3 shows a filter 15 comprising a piezoelectric layer 10b. More specifically, FIG. 3 shows a surface acoustic wave (SAW) filter 15.

Filter 15 comprises the previously-described layers 12 and 14 and a layer 10b obtained by one of the previously-described embodiments.

The manufacturing method, and in particular the characteristics of the ion implantation, is for example configured so that layer 10b has a thickness in the range from 15 μm to 50 μm.

Filter 15 further comprises electrodes 16 located on the upper surface of layer 10b. Electrodes 16 have interdigitated comb shapes, so that acoustic waves propagate at the surface of the piezoelectric material of layer 10b.

FIG. 4 shows another filter 17 comprising a piezoelectric layer 10b. More specifically, FIG. 4 shows a bulk acoustic wave (BAW) filter 17. Filter 17 is, for example, of self-suspended film bulk acoustic resonator (FBAR) type, in which the acoustic insulation is provided by an air cavity 22. For example, filter 17 is adapted to radio frequency waves.

Filter 17 comprises the previously-described layers 12 and 14 and a layer 10b obtained by one of the previously-described embodiments.

Filter 17 further comprises a layer 18 located between bonding layer 14 and layer 10b. Layer 18 is, for example, a layer made of an insulating material. Layer 18 is for example made of silicon oxide.

Filter 17 further comprises a conductive or semiconductor region 20 and a cavity 22 in layer 18, that is, between layer 14 and layer 10b.

Region 20 forms a lower electrode of the filter. Layer 20 is for example made of metal. Layer 20 is preferably flush with the upper surface of layer 18. Thus, the upper surface of region 20 is preferably coplanar with the upper surface of layer 18. Preferably, region 20 partially rests on layer 18. Thus, a portion of the lower surface of region 20 is in contact with layer 18.

Cavity 22 is for example filled with a gaseous element, for example with air. Cavity 22 extends under part of region 20, so that part of the lower surface of region 22 forms part of the walls of cavity 22. Cavity 22 extends, for example, down to the upper surface of layer 18, for example at the level of a side wall of region 20. Cavity 22 thus reaches the lower surface of layer 10b. The cavity is delimited by layer 18, region 20, and layer 10b. Cavity 22 is thus for example closed.

Region 20 and cavity 22 are for example formed prior to the forming of layer 10b. Alternatively, cavity 22 is filled with a sacrificial material until the end of the forming of layer 10b. A relief hole, not shown, running through layer 10b at the level of layer 22 is then formed, so as to remove the sacrificial material via said relief hole.

Filter 17 further comprises a cavity 24 running through layer 10b to reach region 20.

Filter 17 further comprises a conductive or semiconductor region 26 resting on layer 10b, preferably opposite at least a portion of region 20. Region 26 forms an upper electrode of filter 17.

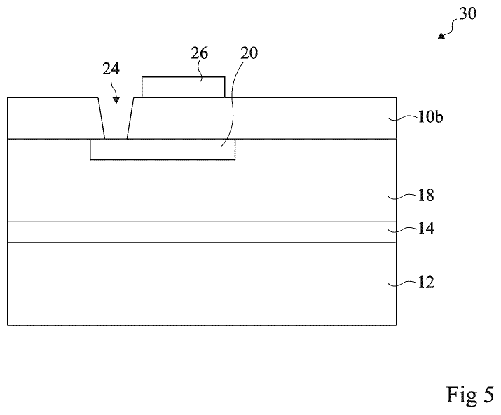

FIG. 5 shows a filter 30 comprising a piezoelectric layer 10b. More specifically, FIG. 5 shows a bulk acoustic wave (BAW) filter 30. Filter 30 is, for example, of solidly mounted resonator (SMR) type. For example, filter 30 is adapted to radio frequency waves.

Filter 30 comprises the previously-described layers 12 and 14 and a layer 10b obtained by one of the previously-described embodiments.

Filter 30 further comprises the layer 18 located between bonding layer 14 and layer 10b. Layer 18 is, for example, a layer made of an insulating material. Layer 18 is for example made of silicon oxide.

Filter 30 further comprises conductive or semiconductor region 20 in layer 18, that is, between layer 14 and layer 10b.

Region 20 forms, as previously, a lower electrode of the filter. Layer 20 is for example made of metal. Layer 20 is preferably flush with the upper surface of layer 18. Thus, the upper surface of region 20 is preferably coplanar with the upper surface of layer 18.

Filter 30 differs from filter 17, among others, in that filter 30 does not comprise cavity 22. Thus, region 20 entirely rests on layer 18. In other words, the lower surface, and preferably the side walls, of region 20 are entirely in contact with layer 18.

Region 20 is for example formed prior to the forming of layer 10b. Filter 30 further comprises cavity 24, or relief hole 24, running through layer 10b so as to reach region 20, providing access to lower electrode 20.

Filter 30 further comprises conductive region 26 resting on layer 10b, preferably facing at least part of region 20. Region 26 forms an electrode of filter 30. Layer 18 forms the Bragg mirror, that is, an alternation of thin layers of materials having a low acoustic impedance, for example SiO₂, SiOC, SiON, and of thin layers of materials having a high acoustic impedance, for example AlN, W, TaN, Ta₂O₅, WO₂, WN, HfO₂, or HfN, enabling to acoustically insulate the resonator from the substrate.

An advantage of the previously-described embodiments is that they enable to form thin films of piezoelectric material comprising no surface defects.

Various embodiments and variants have been described. Those skilled in the art will understand that certain features of these various embodiments and variants could be combined, and other variants will become apparent to those skilled in the art.

Finally, the practical implementation of the described embodiments and variants is within the abilities of those skilled in the art, based on the functional indications given hereabove.

1. Thinning method a first layer made of a piezoelectric material comprising:
a. at least two ion implantations into the first layer so as to amorphize an upper portion of the first layer, the upper portion extending from an upper surface of the first layer, the implantations being performed at different depths, and
b. the removal of the upper portion by a mechanical-chemical polishing step.

2. Method according to claim 1, wherein the first layer is made of a material from among LiNbO₃, LiTaO₃, quartz, langasite, langatate, KNbO₃, K(Ta, Nb)O₃, SrTiO₃, or Pb(Zr, Ti)O₃.

3. Method according to claim 1, wherein the ions comprise hydrogen and/or helium and/or oxygen ions.

4. Method according to claim 1, wherein the first layer is located on a substrate.

5. Method according to claim 1, wherein the first layer is obtained by a grinding step.

6. Method according to claim 1, wherein the method comprises an anneal step between steps a. and b.

7. Method according to claim 1, wherein the characteristics of step a. are such that the rate of removal of the upper portion of the first layer by polishing is at least 10% faster than the rate of removal of a lower portion having received no ions from the first layer by polishing.

8. Method according to claim 7, wherein the lower portion has a thickness smaller than 10 μm.

9. Method according to claim 7, wherein the lower portion has a thickness smaller than 1 μm.

10. Method according to claim 1, wherein the method comprises a plurality of distinct ion implantation steps.

11. Method according to claim 1, wherein the implantations have depths smaller than 500 nm.

12. Method for manufacturing a surface acoustic wave filter comprising:
the forming of a first layer made of a piezoelectric material on a substrate;
the thinning of the first layer by a method according to claim 1;
the forming of electrodes having shapes of interdigitated combs on the first layer.

13. Method for manufacturing a bulk acoustic wave filter comprising:
the forming of a second layer on a substrate;
the forming of a first conductive or semiconductor region in the second layer; and
the forming a first layer on the second layer;
the thinning of the first layer by a method according to claim 1;
the forming of a cavity through the first layer so as to reach the first conductive or semiconductor region;
the forming of a second conductive region on the first layer.

14. Method according to claim 13, wherein the second layer is a Bragg mirror.

15. Method according to claim 14, wherein the method comprises the forming of a cavity comprising a gaseous element between a portion of the first region and the second layer.

16. Method according to claim 12, wherein the filter is adapted to radio frequencies.
